(19) United States
(12) Patent Application Publication
(10) Pub. No.: US 2025/0125389 A1
(43) Pub. Date: Apr. 17, 2025

(54) METHOD FOR CONTROLLING AN OUTPUT POWER OF A BATTERY DEVICE AND AN OPERATING POWER OF A FUEL CELL SYSTEM

(71) Applicant: AVL List GmbH, Graz (AT)

(72) Inventors: Johannes LINDERL, Stainz (AT); Christian Rupert REHRL, Semriach (AT); Christoph SCHÖRGHUBER, St. Peter/Au (AT); Johannes PELL, Temberg (AT)

(73) Assignee: AVL List GmbH, Graz (AT)

(21) Appl. No.: 18/682,142

(22) PCT Filed: Aug. 9, 2022
(86) PCT No.: PCT/AT2022/060279

§ 371 Date: Feb. 8, 2024

(30) Foreign Application Priority Data
Aug. 10, 2021 (AT) A 50651/2021

(51) Int. Cl. H01M 8/04858; B60L 58/40; G01R 31/382; H01M 8/04537; H01M 8/04664; H01M 10/42; H01M 10/48; H01M 16/00

(52) U.S. Cl. CPC H01M 8/04947; B60L 58/40; G01R 31/382; H01M 8/04626; H01M 8/04686; H01M 10/425; H01M 10/48; H01M 16/006; H01M 2220/20; H01M 2250/20

(57) ABSTRACT

The present invention relates to a controlling method for monitoring an output power (OP) of a battery device (110) and an operating poweroperating power (OPP) of a fuel cell system (120) for an electric drive device (130) of a hybrid drive system (100), characterised by the following steps:
measuring and storing the operating poweroperating power (OPP) of the fuel cell system (120) over a measurement period (MP),
measuring and storing the output power (OP) of the battery device (110) over a measurement period (MP),
determining a battery damage forecast (BDF) at least on the basis of the measured and stored output power (OP) of the battery device (110),
determining a fuel cell damage forecast (FCDF) at least on the basis of the measured and stored operating poweroperating power (OPP) of the fuel cell system (120);
specifying a target output power (TOP) for the battery device (110) on the basis of the determined battery damage forecast (BDF),
specifying a target operating power (TOPP) for the fuel cell system (120) on the basis of the determined fuel cell damage forecast (FCDF).

The present invention relates to a controlling method for controlling an output power of a battery device and an operating power of a fuel cell system, a controlling device for carrying out such a method and a hybrid drive system having such a controlling device.

It is known that hybrid drive systems are used to drive modern vehicles equipped with an electric drive device. For this purpose, it is necessary to supply the electric drive device with electrical energy. In such hybrid drive systems, this is supplied from a battery device and a fuel cell system. Depending on the power demand in the respective operating situation of the hybrid drive system, a different combination of the output power and the operating power can be used to meet the current power demand.

A disadvantage of the known solutions is that only the current situation is considered when combining the output power and the operating power to meet the power demand. At most, it is known for individual damage mechanisms of the battery device and/or the fuel cell system to be taken into account in order to avoid or reduce corresponding damage to the individual components. However, the result can be that, while the damage to one of the two components is reduced, the other component with normal or increased damage does not achieve the desired service life for the hybrid drive system.

It is therefore the object of the present invention to remedy, at least partially, the disadvantages described above. In particular, it is the object of the present invention to provide, in a cost-effective and simple manner, the longest possible service life for a hybrid drive system.

The above object is achieved by a controlling method with the features of claim 1, a controlling device with the features of claim 14 and a hybrid drive system with the features of claim 15. Further features and details of the invention are disclosed in the dependent claims, the description and the drawings. Naturally, features and details described in connection with the controlling method according to the invention also apply in connection with the controlling device according to the invention as well as the hybrid drive system according to the invention and vice versa, so that, with regard to disclosure, mutual reference is or can always be made to the individual aspects of the invention.

According to the invention, a controlling method is used to monitor an output power of a battery device and an operating power of a fuel cell system for an electric drive device of a hybrid drive system. Such a controlling method is characterised by the following steps:
measuring and storing the operating power of the fuel cell system over a measurement period,
measuring and storing the output power of the battery device over a measurement period,
determining a battery damage forecast at least on the basis of the measured and stored output power of the battery device,
determining a fuel cell damage forecast at least on the basis of the measured and stored operating power of the fuel cell system,
specifying a target output power for the battery device on the basis of the determined battery damage forecast,
specifying a target operating power for the fuel cell system on the basis of the determined fuel cell damage forecast.

A controlling method according to the invention assumes that, over a longer measurement period during the operation of the hybrid drive system, the operating power of the fuel cell system and the output power of the battery device are not only measured but also stored. For example, the electric output power and the electric operating power can be monitored, measured and stored over a period of several hours, several days or even several weeks. In particular, this makes it possible to determine and take into account the damage status for the fuel cell system and the battery device, which will be explained later. A key component is that a future forecast for the battery device and the fuel cell system can now be determined on the basis of past observations and the stored values for the operating power and the output power. For example, it is possible to use a damage model for the battery device and a further damage model for the fuel cell system which contain the measured and stored values for the operating power and/or the output power. Such a damage model can be used to predict how the damage to the battery device and the fuel cell system will develop in the future. Such a damage forecast can for example include a correlation with a desired minimum service life of the hybrid drive system. However, other damage forecasts, such as a reduction in the maximum possible output power and/or operating power, a maximum storage capacity of the battery device or the like, are also conceivable, individually or in combination.

The core idea of the present invention is that a future assessment is carried out in which, for example using one or more damage models, a battery damage forecast is determined for the battery device and a fuel cell damage forecast is determined for the fuel cell system. For the controlling method described in the following, or the specification steps, in order to meet a current power demand, not only is the current operating situation taken into account but also a damage situation to be expected in the future.

In order to further illustrate the functional principle of the present invention, a known solution is briefly compared with the core idea of the invention. If, for example, the power demand is increased in a known hybrid drive system, this increased power demand must be met either by an increase in operating power, by an increase in output power, or by a combination of both increases. In the known solutions, which of the outputs is increased depends on the current level of the operating power or output power, which limits are specified for maximum or minimum output power or operating power, or which efficiency considerations are to be taken into account in the operation of the fuel cell system and the battery device. However, this can lead to an increased damage effect disproportionately damaging the battery device, so that the desired minimum service life of a determined number of operating hours or the like cannot be achieved.

According to the core idea of the invention, in addition to measuring the current power demand, a controlling method according to the invention is now carried out. For this purpose, the controlling method will take into account the measured and stored operating powers and output powers from the past in order to determine a battery damage forecast and a fuel cell damage forecast. Thus, the monitoring and in particular the specification of the target output power and the target operating power can now be based on the result of these damage forecasts.

In particular, these damage forecasts are compared, in a normalised or absolute manner, with a specified value in order to ensure a minimum service life for the hybrid drive system as a whole, with maximised probability. Thus, while, in known solutions, the increased power demand would have been met by simply increasing the output power of the battery device, for example on the basis of efficiency considerations, in an embodiment according to the invention it is taken into account how the currently determined battery damage forecast affects this. If the currently determined battery damage forecast is to the effect that the battery device will, with a certain probability, not achieve the desired minimum service life, then, despite the increased efficiency achieved if the increased power demand is met from the battery device, the output power of the battery device is not increased; rather, a reduction in efficiency is accepted, so that the power demand is met by increasing the operating power of the fuel cell system, at the same time taking into account the determined battery damage forecast in order also to increase the probability of the battery device achieving the minimum service life. The more frequently a controlling method according to the invention is used to meet power demands in a hybrid drive system, the higher the probability that all sub-components of the hybrid drive system will also achieve the minimum service life as desired.

The measurement periods for the measurement and storage of the operating power and the output power are preferably of the same length and preferably continuous or substantially continuous, i.e. uninterrupted, over the respective operating times. In other words, the measurements are stored over the course of time. In addition to the output power and the operating power, other operating parameters and/or damage parameters for the fuel cell system and/or the battery device can also be measured and stored.

With the help of a controlling method according to the invention, it thus becomes possible to achieve a desired target service life for a vehicle, e.g. a truck, with a high degree of probability. If, for example, a desired target service life of 1.5 million operating kilometres is specified for a truck, the controlling method according to the invention can take into account the forecast for the damage situation of the fuel cell system and the battery device, at least with regard to the individual components of the hybrid drive system, so that the probability of actually achieving or even exceeding this target service life increases.

It has already been mentioned that damage models can be used when forming and determining the respective damage forecast. Such damage models can for example be determined on test benches for the battery device, the fuel cell system and/or the hybrid drive system. Of course, in addition to algorithmic correlations, characteristic maps or the like, neural networks or other forms of artificial intelligence can also be used.

It can be advantageous if, in a controlling method according to the invention, the balance of the fuel cell damage forecast and the battery damage forecast is taken into account for the specification of the target output power and the specification of the target operating power. Here too, a normalisation, as will be explained later, is in particular advantageous for the fuel cell damage forecast and the battery damage forecast. In this way, a balance can be taken into account which leads to the damage mechanisms during the operation of the hybrid drive system causing equal damage, in quantitative terms, to the fuel cell system and the battery device. In particular, a balance can be achieved in this way to compensate for increased damage to one component by conserving this over a certain period of time and allowing increased damage to the other component. Overall, a balancing of damage, or a balancing of the damage which will actually occur in the future, becomes possible by balancing the damage forecasts for the fuel cell system and the battery device.

It can also be advantageous if, in a controlling method according to the invention, a battery damage status for the current damage situation of the battery device and a fuel cell damage status for the current damage situation of the fuel cell system is determined and taken into account for the specification of the target output power and/or the target operating power. In this way, it is possible to determine, in particular in a quantitative and/or normalised manner, how high the current damage situation, in the form of the damage status for the battery device and the fuel cell system, already is. In other words, a past assessment is combined with a future assessment, so that the current damage situation as a result of the mode of operation in the past is correlated with the damage forecast to be expected in the future. Thus, if a high damage forecast with a high level of damage to be expected in the future is combined with a high pre-existing damage status, then this component must be conserved for the future operating situation, while components with a low damage situation, and particularly in combination with a lower damage forecast, can be exposed to increased stress. The aim of this is once again, in particular, to balance out the damage between the individual components in the form of the battery device and the fuel cell system.

It can also bring advantages if, in a controlling method according to the invention, a minimum service life until a maximum battery damage status is achieved and until a maximum fuel cell damage status is achieved is specified for the battery device and the fuel cell system. If the two damage statuses are normalised, the maximum battery damage status represents 100% damage and the maximum fuel cell damage status also represents 100% damage to the fuel cell system. This makes it possible to specify the minimum service life and to base this on a controlling method according to the invention, for example in terms of the desired mileage, a desired number of hours of operation or the like.

It is also advantageous if, in a controlling method according to the invention, the specification of the target operating power and the target output power is carried out taking into account a remaining residual battery damage and/or a remaining residual fuel cell damage. This is done in particular in a normalised manner, for example normalised to a minimum service life for the hybrid drive system. This makes it possible to predict how much residual damage is still present, i.e. how much remains for the future operation of the respective component. Here too, a balancing can be used, but in particular also an adaptation to the desired minimum service life. In this way, the component that has the lower residual damage value can be deliberately conserved. The residual damage can also be used in a normalised manner, in terms of kilometres and/or operating hours, or in an absolute manner.

In addition, it is advantageous if, in a controlling method according to the invention, the battery damage forecast and/or the fuel cell damage forecast, in particular also a battery damage status, a fuel cell damage status, a residual battery damage and/or a residual fuel cell damage, are normalised. A normalisation can for example be carried out in a dimensionless manner. In this case a percentage normalisation to a 100% fulfilment, for example a minimum service life, a minimum number of operating hours and/or a minimum mileage, is also conceivable within the context of the present invention. In particular, normalisation makes it even easier and simpler to carry out monitoring with regard to balancing out the different damage mechanisms of components and/or sub-components.

It is also advantageous if, in a controlling method in accordance with the preceding paragraph, the normalisation is carried out to a minimum service life and/or mileage. This allows a normalisation of damage per future kilometre driven and/or per future operating hour to be inferred, so that a simple and fast comparison makes it possible to carry out a controlling method according to the invention in an accelerated manner.

It also brings advantages if, in a controlling method according to the invention, at least one battery parameter and/or one fuel cell parameter is monitored for the battery damage forecast and/or the fuel cell damage forecast. It is preferable if other damage parameters and/or operating parameters such as pressures, pressure differences, current values, voltage values, temperature values, humidity values and/or similar parameters are also monitored. This makes it possible to evaluate both the forecast, but also, in particular, the previously measured operating power and/or output power, in more detail and to take them into account in a damage model, as will be explained later.

It is also advantageous if, in a controlling method according to the invention, the battery damage forecast and/or the fuel cell damage forecast include sub-component damage forecasts. For example, it may be possible to divide these into partial damage forecasts in order, accordingly, to provide a partial residual damage and/or partial damage status. For example, it is possible to take into account different damage mechanisms in different sub-components of the fuel cell system. For example, a fuel cell system contains damage mechanisms for the membranes contained therein, the catalyst materials used, or the like. The use of sub-component damage forecasts makes it possible to carry out an even more detailed measurement of the individual damage mechanisms here in order to carry out an even more precise balancing, also at the sub-component level, using a controlling method according to the invention.

Further advantages are provided if, in a controlling method according to the invention, only long-term and/or irreversible damage mechanisms are taken into account for the battery damage forecast and/or the fuel cell damage forecast. While short-term or reversible damage mechanisms have little influence on the overall service life of the respective component, this is not the case for long-term and irreversible damage mechanisms. In particular, in the case of irreversible damage mechanisms no regeneration operation is possible in order to return them to a pre-damage state. A focus of the controlling method according to the invention on long-term and irreversible damage mechanisms makes it possible to separate these from reversible short-term damage mechanisms and to achieve the advantages according to the invention in an even more targeted manner.

It is also advantageous if, in a controlling method according to the invention, a damage model is used to determine the battery damage forecast and/or the fuel cell damage forecast. This may for example include a map, an algorithm and/or the use of artificial intelligence. Separate damage models for the fuel cell system and the battery device are also necessary. Of course, partial damage models can also be used for sub-components of the fuel cell system and/or for sub-components of the battery device.

In the case of a controlling method according to the previous paragraph, it may also be advantageous if the damage model is improved on the basis of measured and stored operating powers, on the basis of measured and stored output powers and/or on the basis of other damage parameters. In particular, it is possible to compare an outdated forecast from a previous point in time with the actual measurement and thus evaluate the quality of the old damage forecast. This can be carried out in a qualitative and/or quantitative way. In addition, this evaluation also makes it possible to provide an inference, in the form of a self-learning system, in the damage model, so that erroneous forecasts from the past can be taken into account for future forecasts, which in turn makes future forecasts increasingly accurate with the continued use of a controlling method according to the invention.

It can also be advantageous if, in a controlling method according to the invention, in the event of a negative battery damage forecast and/or negative fuel cell damage forecast, a replacement of the battery device, the fuel cell system, a component of the battery device and/or a component of the fuel cell system is indicated. This is to be understood as signalling when a negative damage forecast is interpreted in such a way that it is not guaranteed that the minimum service life will be achieved. For example, the damage forecast may contain the information that the desired minimum service life cannot be achieved even with maximum conservation and/or the use of regeneration situations. In such a case, a sub-component can be replaced at an early stage in order to avoid, at an early stage, a sudden replacement involving a standstill of the hybrid drive system in the future. In particular, this signalling is selected in such a way that a component which is particularly easy and cheap to replace is selected which can now be subjected to maximum load at an early stage, avoiding any conservation, while conserving the remaining components.

A further subject matter of the present invention is a controlling device for monitoring an output power of a battery device and an operating power of a fuel cell system for an electric drive device of a hybrid drive system. Such a controlling device is characterised by a measuring module for measuring and storing the operating power of the fuel cell system over a measurement period and for measuring and storing the output power of the battery device over a measurement period. Furthermore, a determination module is provided to determine a battery damage forecast at least on the basis of measured and stored output power of the battery device and to determine the fuel cell damage forecast at least on the basis of the measured and stored operating power of the fuel cell system. In addition, the controlling device has a specification module for specifying a target output power for the battery device on the basis of the determined battery damage forecast and for specifying a target operating power for the fuel cell system on the basis of the determined fuel cell damage forecast. The measuring module, the determination module and/or the specification module are designed to carry out a controlling method according to the invention, so that a controlling device according to the invention has the same advantages as have been explained in detail with reference to a controlling method according to the invention.

In addition, the subject matter of the present invention includes a hybrid drive system for driving a vehicle. Such a hybrid drive system has a battery device, a fuel cell system, an electric drive device and a controlling device according to the invention, so that such a hybrid drive system has the same advantages as have been explained in detail with reference to a controlling device according to the invention and a controlling method according to the invention.

Further advantages, features and details of the invention are explained in the following description, in which exemplary embodiments of the invention are described in detail with reference to the drawings. In each case schematically:

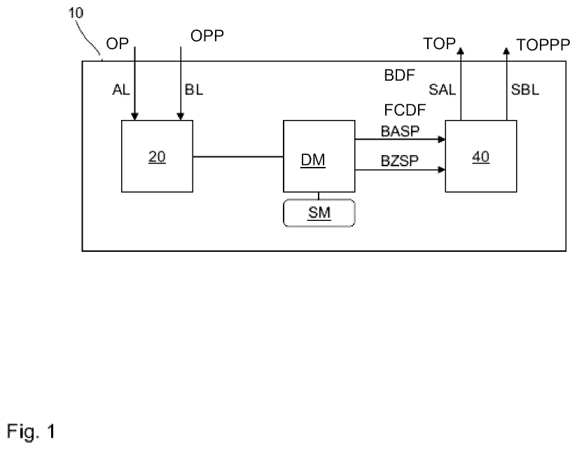

FIG. 1 shows an embodiment of a controlling device according to the invention,

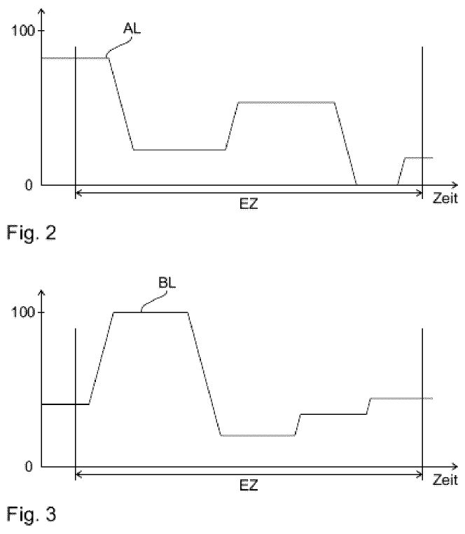

FIG. 2 shows a possible curve of an output power over a measurement period,

FIG. 3 shows a possible curve of an operating power over a measurement period,

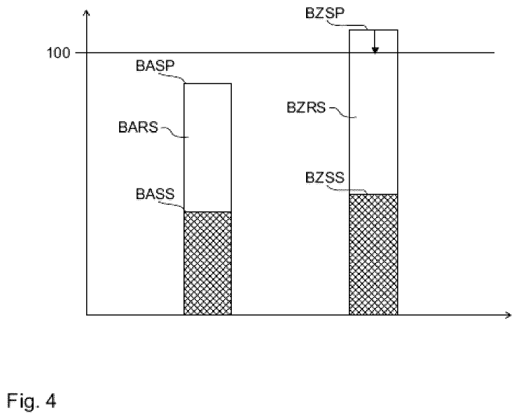

FIG. 4 shows a possible implementation of a method according to the invention,

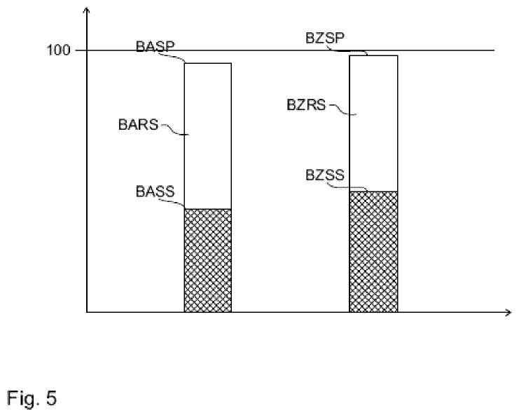

FIG. 5 shows a further possible implementation of a method according to the invention,

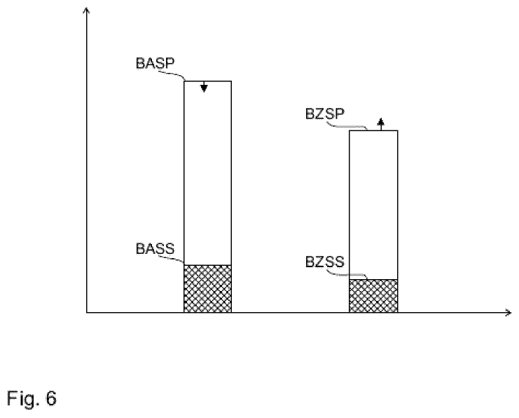

FIG. 6 shows a further possible implementation of a method according to the invention,

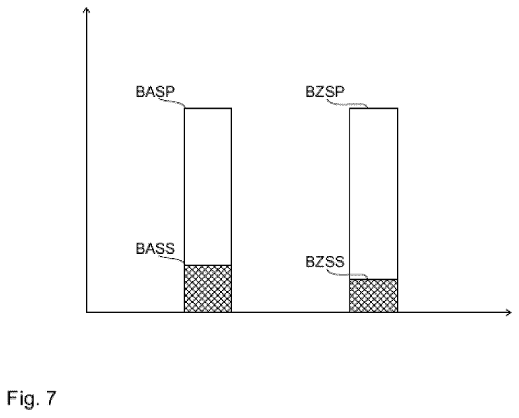

FIG. 7 shows a further possible implementation of a method according to the invention,

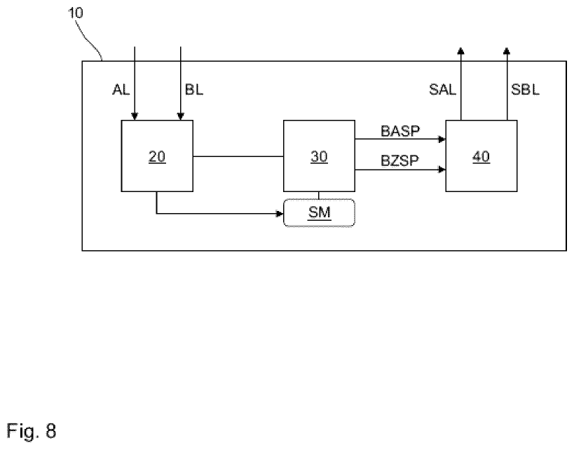

FIG. 8 shows a further embodiment of a controlling device according to the invention and

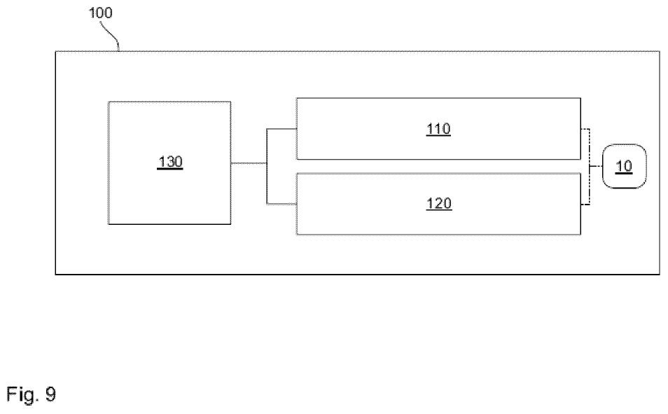

FIG. 9 shows an embodiment of a hybrid drive system according to the invention.

FIG. 1 shows schematically a controlling device 10 which is equipped with a measuring module 20. Using sensor modules, which are not represented in detail, the measuring module 20 can continuously measure and store the current output power OP of a battery device 110 and the current operating power OPP of a fuel cell system 120. Accordingly, such a measuring module 20 is preferably also equipped with a storage unit. The continuous and ongoing measurement of the output power OP and the operating power OPP allows a battery damage forecast BDF and a fuel cell damage forecast FCDF to be provided, based on and using a damage model DM, with the help of the determination module 30. These two damage forecasts BDF and FCDF are now finally used in the specification module 40 in order to be able to provide a target output power TOP and a target operating power TOPP for the operation of the fuel cell system 120 and the battery device 110. This application is represented in FIG. 9 in a hybrid drive system 100, whereby it can clearly be seen that an electric drive device 130, for example in the form of an electric motor, can now be supplied with the desired electrical energy to drive a vehicle from the battery device 110 alone, from the fuel cell system 120 alone or, in combination, from the battery device 110 together with the fuel cell system 120.

The basis of a controlling method according to the invention is the measurement of the (output) power OP and the operating power OPP over a measurement period MP, as shown for example in FIGS. 2 and 3. Depending on the power demand and operating situation, the (output) power OP and the operating power OPP fluctuate over time. An exemplary progression can be seen in the two FIGS. 2 and 3. For example, the output power OP of the battery device 110 fluctuates from a high value to a low value to a medium value and, via a completely switched-off value, back to a low value over the measurement period MP. FIG. 3 shows the operating power OPP of the fuel cell system 120, which is never completely switched off and fluctuates between a maximum utilisation and varying degrees of low utilisation. In FIGS. 2 and 3, the two measurement periods MP are preferably of the same length and are in addition preferably measured and stored continuously and without gaps.

A possibility of an effect of a controlling method according to the invention is shown in FIGS. 4 and 5. FIG. 4 shows how three values can be determined on the basis of past situations and accordingly on the basis of the measured and stored output powers OP and operating powers OPP. The first value is the evaluation of the past in the form of a battery damage status BDS and a fuel cell damage status FCDS. In this case, the fuel cell damage status FCDS is slightly above the battery damage status BDS. On this basis, a damage forecast for the battery damage forecast BDF and the fuel cell damage forecast FCDF can now be estimated for the expected future operation, for example on the basis of a vehicle cycle or a usually applicable combination of different operating situations. In FIG. 4, the individual damage forecasts and the other parameters are normalised to 100%. The 100% represents maximum damage for the desired minimum service life. In FIG. 4 it can thus be seen that the fuel cell damage forecast FCDF exceeds 100% and thus a damage forecast results which excludes achieving the minimum service life. At the same time, the battery damage forecast BDF is below this normalised 100%, so that in this situation the battery device 110 will achieve the minimum service life. The difference between the damage forecasts BDF and FCDF and the damage status BDS and FCDS can each be seen here as residual damage in the form of the residual battery damage RBD and the residual fuel cell damage RFCD.

In order to take into account the undesirable situation of FIG. 4 with a controlling method according to the invention, the specification of the target operating power TOPP and the target output power TOP is carried out in such a way that the fuel cell system 120 is conserved and, accordingly, a higher output power OP is demanded from the battery device 110. This is the case even if this means that the battery device 110 is operated with greater damage and/or with less efficiency. That is to say, in contrast to the known controlling devices, damaging or inefficient operating modes are for example demanded of the battery device 110 in order to reduce future damage and an expected damage forecast for the fuel cell system 120, to such an extent that a situation such as that shown in FIG. 5 is achieved. This shows the result of a monitoring intervention according to the invention. Due to the increased damage to the battery device 110, the battery damage forecast BDF has increased, while due to the conservation of the fuel cell system 120, the fuel cell damage forecast FCDF has now fallen below 100% in the normalised representation. Thus, the effect of a controlling method according to the invention is clearly visible. Despite the recognition in the first step of excessive damage and the fact that the fuel cell damage status FCDS was too high for this point in time, as a result of the monitoring intervention the two components, in the form of the battery device 110 and the fuel cell system 120, are now again below the normalised 100% for the minimum service life and thus the desired minimum service life can, with a high degree of probability, be achieved.

FIGS. 6 and 7 show a further possibility of a controlling method according to the invention. No combination with a minimum service life is shown here, and nor is normalisation strictly necessary. FIG. 6 shows an initial situation with a slightly higher battery damage status BDS above a fuel cell damage status FCDS. The fuel cell damage forecast FCDF is significantly lower than the battery damage forecast BDF. As the two small arrows indicate, a targeted balancing of the damage is desired here, so that an adjustment of the damage forecast is for example desired. In this situation, additional and increased damage to the fuel cell system 130 can therefore be accepted in order to lower the battery damage forecast BDF in order to balance the damage. The result of a specification of target output powers TOP and target operating powers TOPP generated on this basis is shown in FIG. 7, so that the result is in effect a balance between the battery damage forecast BDF and the fuel cell damage forecast FCDF.

FIG. 8 again shows a further development of the embodiment of a controlling device 10 shown in FIG. 1. In this case, a feedback possibility is provided in that the damage model DM can be designed as a self-learning system for the determination of the BDF and FCDF forecasts. This can be done on the basis of past damage forecasts BDF and FCDF and comparison with damage which has actually occurred. However, it is also possible to use other damage parameters, operating parameters or the measured output powers OP and operating powers OPP.

The above explanation of the embodiments describes the present invention exclusively in the context of examples.

### LIST OF REFERENCE SIGNS

10 controlling device
20 measuring module
30 determination module
40 specification module
100 hybrid drive system
110 battery device
120 fuel cell system
130 electric drive device
OP output power
TOP target output power
OPP operating power
TOPP target operating power
MP measurement period
DM damage model
BDF battery damage forecast
BDS battery damage status
RBD residual battery damage
FCDF fuel cell damage forecast
FCDS fuel cell damage status
RFCD residual fuel cell damage

1. Controlling method for controlling an output power of a battery device and an operating poweroperating power of a fuel cell system for an electric drive device of a hybrid drive system, characterised by the following steps:
measuring and storing the operating poweroperating power of the fuel cell system over a measurement period,
measuring and storing the output power of the battery device (110) over a measurement period,
determining a battery damage forecast at least on the basis of the measured and stored output power of the battery device,
determining a fuel cell damage forecast at least on the basis of the measured and stored operating poweroperating power of the fuel cell system;
specifying a target output power for the battery device on the basis of the determined battery damage forecast,
specifying a target operating power for the fuel cell system (120) on the basis of the determined fuel cell damage forecast.

2. Controlling method according to claim 1, wherein the balance of the fuel cell damage forecast and the battery damage forecast is taken into account for the specification of the target output power and the specification of the target operating power.

3. Controlling method according to claim 1, wherein a battery damage status for the current damage situation of the battery device and a fuel cell damage status for the current damage situation of the fuel cell system is determined and taken into account for the specification of the target output power and/or the target operating power.

4. Controlling method according to claim 1, wherein a minimum service life until a maximum battery damage status is achieved and until a maximum fuel cell damage status is achieved is specified for the battery device and the fuel cell system.

5. Controlling method according to claim 4, wherein the specification of the target output power and the target operating power is carried out taking into account a remaining residual battery damage and/or a remaining residual fuel cell damage.

6. Controlling method according to claim 1, wherein the battery damage forecast and/or the fuel cell damage forecast, in particular also a battery damage status, a fuel cell damage status, a residual battery damage and/or a residual fuel cell damage are normalised.

7. Controlling method according to claim 6, wherein the normalisation relates to a minimum service life and/or to a mileage.

8. Controlling method according to claim 1, wherein at least one battery parameter and/or a fuel cell parameter is monitored for the battery damage forecast and/or the fuel cell damage forecast.

9. Controlling method according to claim 1, wherein the battery damage forecast and/or the fuel cell damage forecast include sub-component damage forecasts.

10. Controlling method according to claim 1, wherein only long-term and/or irreversible damage mechanisms are taken into account for the battery damage forecast and/or the fuel cell damage forecast.

11. Controlling method according to claim 1, wherein a damage model is used to determine the battery damage forecast and/or the fuel cell damage forecast.

12. Controlling method according to claim 11, wherein the damage model is improved on the basis of measured and stored operating power, on the basis of measured and stored output power and/or on the basis of other damage parameters.

13. Controlling method according to claim 1, wherein in the event of a negative battery damage forecast and/or negative fuel cell damage forecast, a replacement of the battery device, the fuel cell system, a component of the battery device and/or a component of the fuel cell system is indicated.

14. Controlling device for monitoring an output power of a battery device and an operating poweroperating power of a fuel cell system for an electric drive device of a hybrid drive system, characterised by a measuring module for measuring and storing the operating poweroperating power of the fuel cell system over a measurement period and for measuring and storing the output power of the battery device over a measurement period and for measuring and storing the output power of the battery device over a measurement period, a determination module for determining a battery damage forecast at least on the basis of the measured and stored output power of the battery device and for determining a fuel cell damage forecast at least on the basis of the measured and stored operating poweroperating power of the fuel cell system, as well as a specification module for specifying a target output power for the battery device on the basis of the determined battery damage forecast and for specifying a target operating power for the fuel cell system on the basis of the determined fuel cell damage forecast, wherein the measuring module, the determination module and/or the specification module are designed to carry out a controlling method with the features of claim 1.

15. Hybrid drive system for a vehicle drive, having a battery device, a fuel cell system, an electric drive device and a controlling device with the features of claim 14.
